(19) United States
(12) Patent Application Publication
(10) Pub. No.: US 2025/0056791 A1
(43) Pub. Date: Feb. 13, 2025

(54) SEMICONDUCTOR DEVICE INCLUDING STORAGE NODES AND METHOD OF MANUFACTURING THE SAME

(71) Applicant: SK hynix Inc., Gyeonggi-do (KR)

(72) Inventor: Heon Yong CHANG, Gyeonggi-do (KR)

(21) Appl. No.: 18/393,082

(22) Filed: Dec. 21, 2023

(30) Foreign Application Priority Data
Aug. 7, 2023 (KR) 10-2023-0102841

(51) Int. Cl. H10B 12/00

(52) U.S. Cl. CPC H10B 12/315; H10B 12/0335

(57) ABSTRACT

A method of manufacturing a semiconductor device including the array of conductive patterns is presented. The semiconductor device may include first conductive patterns disposed over an insulating layer over a semiconductor substrate, a second conductive pattern disposed to extend lengthwise to the side of the first conductive patterns, and third conductive patterns connected to the first conductive patterns and the second conductive pattern. The third conductive patterns may be storage nodes of a capacitor.

### CROSS-REFERENCE TO RELATED APPLICATION

The present application claims priority under 35 U.S.C. § 119 (a) to Korean Patent Application No. 10-2023-0102841, filed in the Korean Intellectual Property Office on Aug. 7, 2023, the entire disclosure of which is incorporated herein by reference.

### BACKGROUND

### 1. Technical Field

The present disclosure relates to an integrated circuit device, and particularly, to a semiconductor device including storage nodes and a method of manufacturing the same.

### 2. Related Art

Integrated circuit devices may be integrated in a semiconductor substrate to constitute semiconductor devices. As the semiconductor device has been miniaturized, the size, width, or critical dimension of each of conductive patterns that constitute the integrated circuit devices is reduced, and a space between the conductive patterns is rapidly reduced. The semiconductor devices may require capacitor elements as their data storage elements. As the width or critical dimension of each of storage nodes of a capacitor is reduced, the heights of the storage nodes are increased in order to secure capacitance. As a result, a defect in which some of the storage nodes are lost may occur at an edge part of a region in which the storage nodes have been arranged.

### SUMMARY

The present invention overcomes the aforementioned limitations of the state of the art.

According to a first aspect of the present invention, a semiconductor device is provided. The semiconductor device may include first conductive patterns disposed over an insulating layer over a semiconductor substrate, a second conductive pattern disposed to extend lengthwise to a side of the first conductive patterns over the insulating layer, and third conductive patterns connected to the first conductive patterns and the second conductive pattern.

According to another aspect of the present invention, a method of manufacturing the inventive semiconductor device is provided. The method may include forming a first insulating layer within a semiconductor substrate, simultaneously forming, over the first insulating layer, first conductive patterns and a second conductive pattern that extend lengthwise to a side of the first conductive patterns, and forming third conductive patterns that are connected to the first conductive patterns and the second conductive pattern.

These and other aspects, embodiments, features and advantages of the present invention will become apparent from the following detailed description of specific embodiments of the invention in conjunction with the following drawings.

### BRIEF DESCRIPTION OF THE DRAWINGS

FIGS. 1 to 15 are simplified schematic diagrams illustrating a semiconductor device and a method of manufacturing the same according to an embodiment of the present invention.

FIG. 16 is a simplified schematic plan view illustrating an array of conductive patterns of a semiconductor device according to an embodiment of the present invention.

FIG. 17 is a simplified schematic plan view illustrating an array of conductive patterns of a semiconductor device according to an embodiment of the present invention.

FIG. 18 is a simplified schematic plan view illustrating an array of conductive patterns of a semiconductor device according to an embodiment of the present invention.

### DETAILED DESCRIPTION

Any terms which are not specifically defined in this specification may be interpreted according to their commonly recognized or plain meaning as understood by those skilled in the art. Terms such as “first,” “second,” “third,” “fourth,” “fifth,” and the like, are used to distinguish between elements and are not used to limit the elements themselves or to mean a specific order.

Embodiments of the present invention may be applied to various technical fields employing semiconductors including technical fields for implementing integrated circuit devices, such as DRAM, PCRAM, and/or ReRAM devices. Furthermore, embodiments of the present invention may also be applied to a technical field for implementing a memory device that stores data or a logic device that performs a logical operation. Moreover, embodiments of the present invention may be applied to a technical field for implementing various products that require conductive patterns having fine sizes.

It is noted that in the various drawings, same reference numerals denote same components. Accordingly, the same reference numerals or similar reference numerals may be described with reference to other drawings although they are not mentioned or described in corresponding drawings. Furthermore, although reference numerals in a drawing are not shown, they may be described with reference to other drawings.

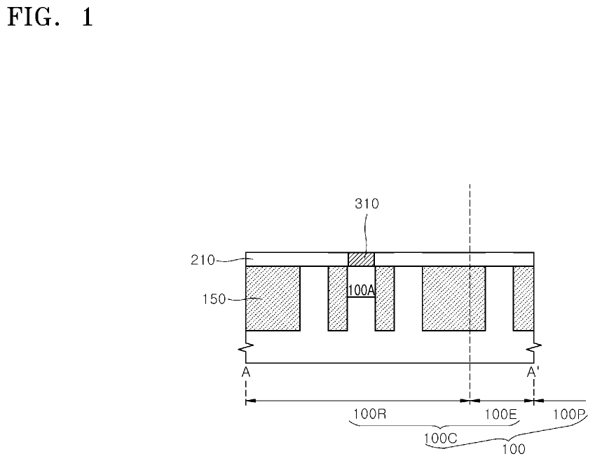

FIGS. 1 to 15 are simplified schematic diagrams illustrating a semiconductor device and a method of manufacturing the same according to an embodiment.

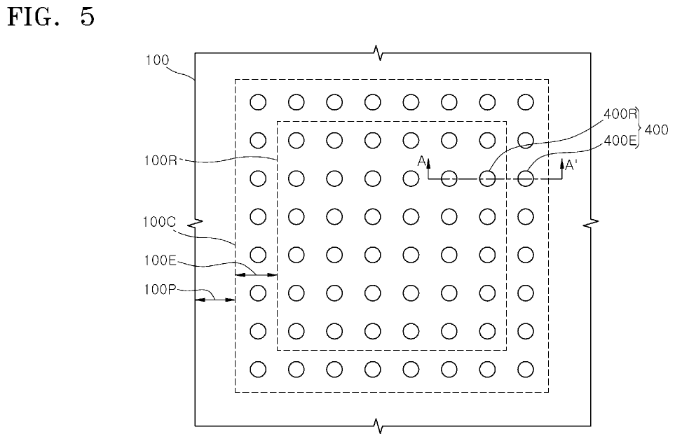

Referring now to FIG. 1, an under conductive contact 310 or under conductive contacts 310 may be formed on a semiconductor substrate 100. FIG. 1 is a cross-sectional view taken along line A-A′ in FIG. 5. The semiconductor substrate 100 may include a cell region 100C and a peripheral region 100P. In a DRAM semiconductor device, the cell region 100C may indicate a cell array, and the peripheral region 100P may indicate a core region. The peripheral region 100P may be a region outside the cell region 100C or a region that surrounds the cell region 100C. The cell region 100C of the semiconductor substrate 100 may include first and second regions 100R and 100E. The second region 100E may be located outside the first region 100R and/or may surround the first region 100R. The second region 100E may be located at an edge region of the cell region 100C. The second region 100E may form a boundary between the first region 100R and the peripheral region 100P. Memory devices or memory elements may be integrated in the cell region 100C. Circuits that control operations of the memory devices may be disposed in the peripheral region 100P. The memory devices or memory elements may include transistors and/or capacitors. The control circuits may include a sense amplifier or a sub-word line driver (SWD).

An isolation layer 150 that defines active regions 100A may be formed in the semiconductor substrate 100. The isolation layer 150 may include a field oxide layer. The isolation layer 150 may include a dielectric material (also referred to as an insulating material) such as silicon oxide (SiO₂) or silicon nitride (Si₃N₄). The semiconductor substrate 100 may include a semiconductor material such as silicon (Si). The silicon substrate may further include a semiconductor material such as germanium (Ge). The semiconductor substrate 100 may include a compound semiconductor material, such as silicon carbide (SiC), gallium arsenide (GaAs), indium arsenide (InAs), or indium phosphide (InP). The semiconductor substrate 100 may have a wafer form.

Impurities may be doped into the active regions 100A of the semiconductor substrate 100. The impurity-doped region may act as a source region or drain region of a transistor.

An under insulating layer 210 may be formed over the semiconductor substrate 100. The under conductive contact 310 that substantially penetrates the under insulating layer 210 may be formed. The under insulating layer 210 may cover and insulate the semiconductor substrate 100. The under insulating layer 210 may include an insulating material. The under insulating layer 210 may include a dielectric material such as silicon oxide (SiO₂). An opening or openings that penetrate the under insulating layer 210 may be formed. The opening or each of the openings may be a through hole that exposes a part of the semiconductor substrate 100 or a part of the active regions 100A of the semiconductor substrate 100.

A conductive layer that fills the opening or the openings may be formed on the under insulating layer 210. The conductive layer may be separated as the under conductive contact 310 or into the under conductive contacts 310. The conductive layer or the under conductive contact 310 may include a conductive material, such as polysilicon (a polycrystalline silicon layer) into which impurities have been doped. The conductive layer may be etched back or subjected to chemical mechanical polishing (CMP) so that a surface of the under insulating layer 210 is exposed. The under insulating layer 210 may electrically isolate or electrically insulate the under conductive contact 310. A gate or word line of a transistor may be further formed over the semiconductor substrate 100 before the under insulating layer 210 is formed.

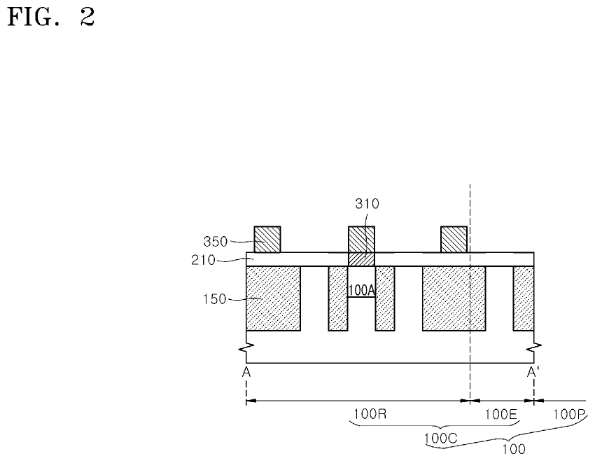

Referring to FIG. 2, under conductive patterns 350 may be formed over the under insulating layer 210. A conductive layer may be formed over the under insulating layer 210. The conductive layer may be separated into or patterned as the under conductive patterns 350. The conductive layer may be separated into the under conductive patterns 350 by selectively removing some parts of the conductive layer. One of the under conductive patterns 350 may be formed to be connected to the under conductive contact 310. The under conductive contact 310 may electrically connect the under conductive pattern 350 to the active region 100A of the semiconductor substrate 100.

The under conductive pattern 350 or the under conductive patterns 350 may form a bit line pattern. The under conductive contact 310 or the under conductive contacts 310 may form a bit line contact or a bit line plug. The under conductive pattern 350 or each of the under conductive patterns 350 may include a metal layer such as, for example, tungsten (W). The under conductive pattern 350 or each of the under conductive patterns 350 may further include a barrier metal layer, such as titanium nitride (TiN), tungsten nitride (WN), titanium tungsten nitride (TiWN), or tungsten silicon nitride (WSiN), or a complex layer of titanium nitride (TIN), tungsten nitride (WN), titanium tungsten nitride (TiWN), or tungsten silicon nitride (WSiN).

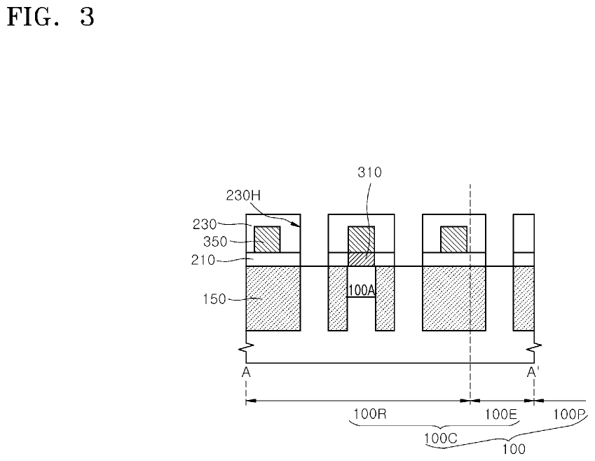

Referring to FIG. 3, a first insulating layer 230 that covers the under conductive patterns 350 may be formed over the under insulating layer 210. The first insulating layer 230 may include an insulating material. The first insulating layer 230 may include a dielectric material such as silicon oxide (SiO₂). An opening 230H or openings 230H that penetrate the first insulating layer 230 and the under insulating layer 210 may be formed. The opening 230H or each of the openings 230H may be formed as a through hole that exposes a part of the semiconductor substrate 100 or that exposes some of the active regions 100A of the semiconductor substrate 100.

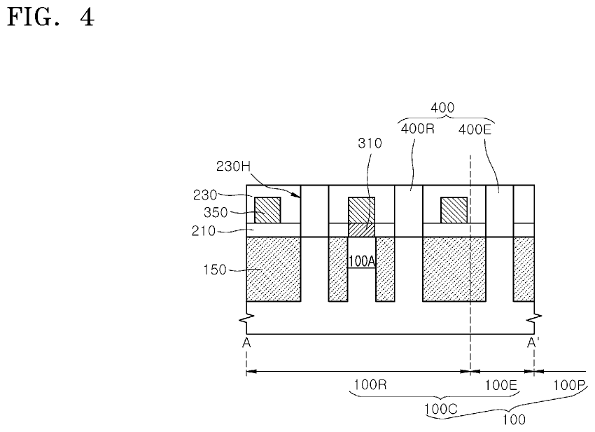

Referring to FIGS. 4 and 5, conductive contacts 400 that fill the openings 230H of the first insulating layer 230 may be formed. FIG. 4 illustrates a cross-sectional view taken along line A-A′ in FIG. 5. A conductive layer that fills the openings 230H may be formed on the first insulating layer 230. The conductive layer may be separated into or patterned as the conductive contacts 400. The conductive layer may be etched back or subjected to CMP so that a surface of the first insulating layer 230 is exposed. The first insulating layer 230 may electrically isolate or electrically insulate the conductive contacts 400. The conductive contacts 400 may penetrate the first insulating layer 230 and the under insulating layer 210 to electrically connect each one to a respective one of the active regions 100A of the semiconductor substrate 100. The conductive contacts 400 may have a pillar form or a plug form. The conductive contacts 400 may each include polysilicon into which impurities have been doped or a conductive material, such as, for example, tungsten (W). The conductive contacts 400 may be formed in a pattern so that each one of the conductive contacts 400 passes between a respective pair of adjacent conductive patterns 350.

As presented in FIG. 5, the conductive contacts 400 may be formed in a pattern so that the conductive contacts 400 are spaced apart from each other and arranged at predetermined intervals. The conductive contacts 400 may be disposed in an array within the cell region 100C of the semiconductor substrate 100. The under conductive contact 310 may be disposed between the conductive contacts 400. The conductive contacts 400 may be divided into first conductive contacts 400R and second conductive contacts 400E. The first conductive contacts 400R, that is, some of the conductive contacts 400, may be disposed within the first region 100R of the semiconductor substrate 100. The second conductive contacts 400E, that is, some others of the conductive contacts 400, may be disposed within the second region 100E of the semiconductor substrate 100. The second conductive contacts 400E may be aligned to surround the first conductive contacts 400R. In FIG. 5, an example in which the second conductive contacts 400E have been disposed to form a first column along the second region 100E of the semiconductor substrate 100 has been presented. However, the second conductive contacts 400E may be aligned to a plurality of columns, such as including first and second columns or first, second and third columns.

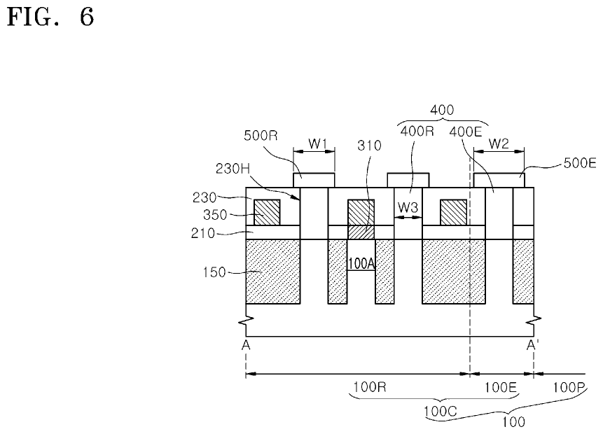

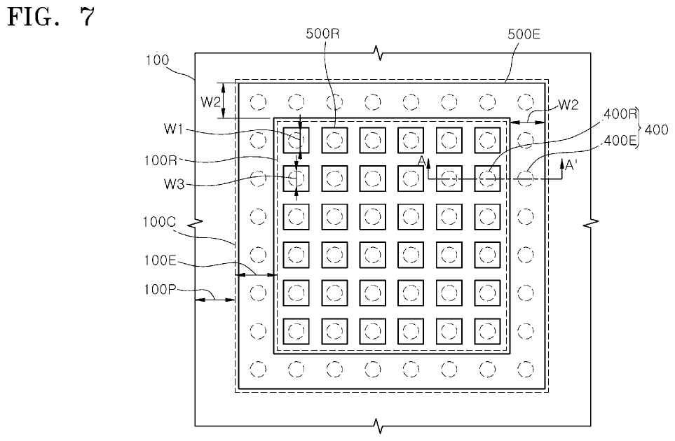

Referring to FIGS. 6 and 7, a plurality of first conductive patterns 500R and a second conductive pattern 500E may be formed over the first insulating layer 230. The first conductive patterns 500R may be patterned as patterns each having a feature different from the feature of the second conductive pattern 500E. A conductive layer may be formed over the first insulating layer 230 and then some parts of the conductive layer may be removed by selectively etching the some parts to form the first and second conductive patterns 500R and 500E. The first conductive patterns 500R and the second conductive pattern 500E may be formed simultaneously through such patterning process. The first and second conductive patterns 500R and 500E may each include a metal material such as, for example, tungsten (W). The first and second conductive patterns 500R and 500E may each further include a barrier layer. The barrier layer may be made of any suitable material including, for example, titanium (Ti), tungsten nitride (TiN), or tungsten silicon nitride (WSIN). The barrier layer may block the diffusion or movement of metal ions.

The first conductive patterns 500R may be arranged within the first region 100R of the semiconductor substrate 100 while being spaced apart from each other at predetermined intervals. The first conductive patterns 500R may be formed to have island features, respectively, which are spaced apart from each other and arranged at predetermined intervals. The second conductive pattern 500E may be disposed to extend lengthwise to the side of the first conductive patterns 500R over the first insulating layer 230. The second conductive pattern 500E may have a line form feature or a bar shape extending lengthwise along the second region 100E of the semiconductor substrate 100. The line form feature of the second conductive pattern 500E may be formed to laterally face the island features of the first conductive patterns 500R.

The second conductive pattern 500E may have a greater width than the first conductive pattern 500R. A width W2 of the second conductive pattern 500E may be greater than a width W1 of the first conductive pattern 500R. The second conductive pattern 500E may have a form feature extending to surround the first conductive patterns 500R or the outside of the array of the first conductive patterns 500R. The second conductive pattern 500E may surround the first conductive patterns 500R or the outside of the array of the first conductive patterns 500R in a ring form feature.

The conductive contacts 400 may be coupled or connected to the first conductive patterns 500R and the second conductive pattern 500E. The conductive contacts 400 may penetrate the first insulating layer 230, and may electrically connect the first conductive patterns 500R and the second conductive pattern 500E to the active regions 100A of the semiconductor substrate 100. The first conductive contacts 400R, that is, some of the conductive contacts 400, may be connected to the first conductive patterns 500R, respectively. The first conductive patterns 500R may be formed to overlap the first conductive contacts 400R, respectively, so that the first conductive contacts 400R and the first conductive patterns 500R are connected in a one-to-one way. The second conductive contacts 400E, that is, some others of the conductive contacts 400, may be connected to the second conductive pattern 500E. The plurality of second conductive contacts 400E may be connected to one second conductive pattern 500E.

The first and second conductive patterns 500R and 500E may have the widths W1 and W2, respectively. Each of the widths W1 and W2 is greater than the diameter or width W3 of the conductive contact 400. Accordingly, the possibility that the first conductive patterns 500R and the second conductive pattern 500E may be connected to the conductive contact 400 may be improved even in a case where the first and second conductive patterns 500R and 500E depart from their original positions where the first and second conductive patterns 500R and 500E are in contact with the conductive contacts 400.

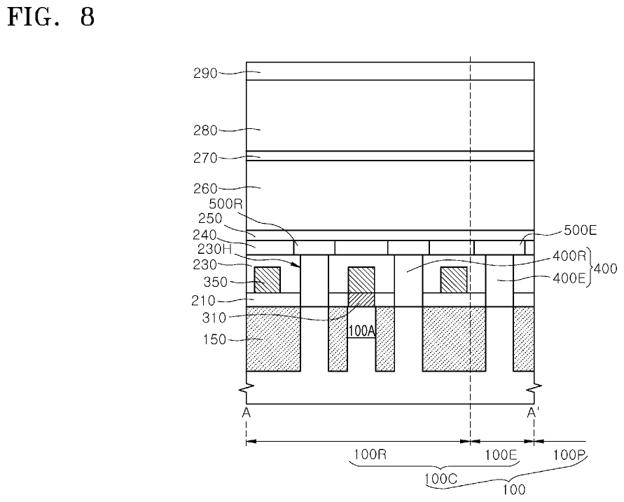

Referring to FIG. 8, an etch stop layer 250 may be formed covering the first and second conductive patterns 500R and 500E. The etch stop layer 250 may be formed of a dielectric material or an insulating material. For example, the etch stop layer 250 may include silicon nitride (Si₃N₄). Before the etch stop layer 250 is formed, a second insulating layer 240 isolating the first and second conductive patterns 500R and 500E from each other may be further formed over the first insulating layer 230. The second insulating layer 240 may be formed of a dielectric material layer or an insulating material layer that is different from the dielectric material or insulating material of the etch stop layer 250. The second insulating layer 240 may include a dielectric material layer or an insulating material layer which may have etch selectivity because the second insulating layer 240 has an etch rate different from the etch rate of the etch stop layer 250. For example, the second insulating layer 240 may be formed of silicon oxide (SiO₂).

A first sacrificial layer 260 may be formed over the etch stop layer 250. The first sacrificial layer 260 may include a dielectric material layer or an insulating material layer that is different from the dielectric material layer or insulating material layer of the etch stop layer 250. The first sacrificial layer 260 may include a dielectric material layer or an insulating material layer which may have etch selectivity because the first sacrificial layer 260 has an etch rate different from the etch rate of the etch stop layer 250. The first sacrificial layer 260 may include silicon oxide such as, for example, borophosphosilicate glass (BPSG).

A first floating support layer 270 may be formed over the first sacrificial layer 260. The first floating support layer 270 may include a dielectric material layer or an insulating material layer that is different from the dielectric material layer or insulating material layer of the first sacrificial layer 260. The first floating support layer 270 may include a dielectric material layer or an insulating material layer which may have etch selectivity because the first floating support layer 270 has an etch rate different from the etch rate of the first sacrificial layer 260. The first floating support layer 270 may include silicon nitride (Si₃N₄). The first floating support layer 270 may be formed of a layer having a smaller thickness than the first sacrificial layer 260.

A second sacrificial layer 280 may be formed over the first floating support layer 270. The second sacrificial layer 280 may include a dielectric material layer or an insulating material layer that is different from the dielectric material layer or insulating material layer of the first floating support layer 270. The second sacrificial layer 280 may include a dielectric material layer or an insulating material layer which may have etch selectivity because the second sacrificial layer 280 has an etch rate different from the etch rate of the first floating support layer 270. The second sacrificial layer 280 may include a silicon oxide layer such as, for example, a tetraethyl ortho silicate (TEOS) layer.

A second floating support layer 290 may be formed over the second sacrificial layer 280. The second floating support layer 290 may include a dielectric material layer or an insulating material layer that is different from the dielectric material layer or insulating material layer of the second sacrificial layer 280. The second floating support layer 290 may include a dielectric material layer or an insulating material layer which may have etch selectivity because the second floating support layer 290 has an etch rate different from the etch rate of the second sacrificial layer 280. The second floating support layer 290 may include silicon nitride (Si₃N₄). The second floating support layer 290 may be formed of a layer having a smaller thickness than the second sacrificial layer 280.

The second sacrificial layer 280 and the second floating support layer 290 may be omitted. An additional sacrificial layer and an additional floating support layer may be further formed over the second floating support layer 290.

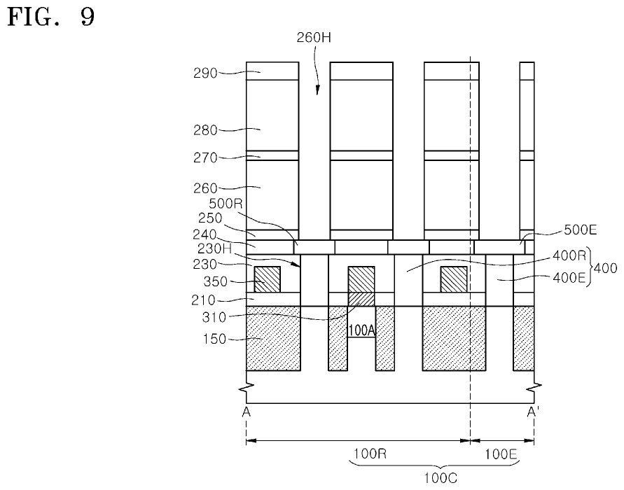

Referring to FIG. 9, openings 260H that penetrate the second floating support layer 290, the second sacrificial layer 280, the first floating support layer 270, the first sacrificial layer 260, and the etch stop layer 250 may be formed. Some parts of the second floating support layer 290, the second sacrificial layer 280, the first floating support layer 270, the first sacrificial layer 260, and the etch stop layer 250 may be selectively etched or removed by performing a photolithography process and a selective etch process. The openings 260H may each be formed in the form of a through hole that penetrates the second floating support layer 290, the second sacrificial layer 280, the first floating support layer 270, the first sacrificial layer 260, and the etch stop layer 250. Some of the openings 260H may be formed to be aligned with the first conductive patterns 500R, and some others of the openings 260H may be formed to be aligned with the second conductive pattern 500E. Some of the openings 260H may be formed to expose the first conductive patterns 500R, respectively, and some others of the openings 260H may be formed to expose some parts of the second conductive pattern 500E.

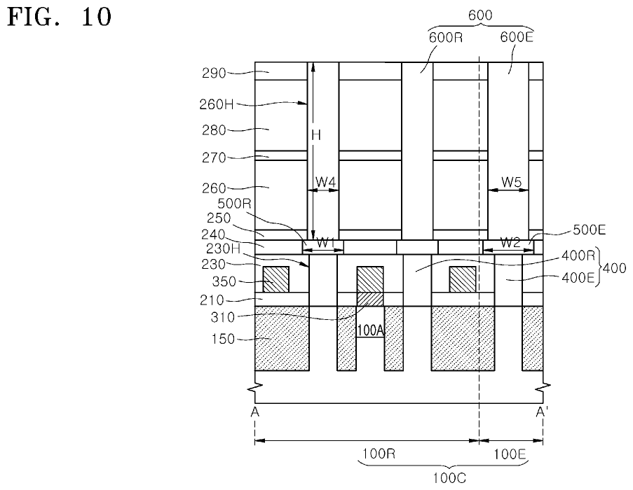

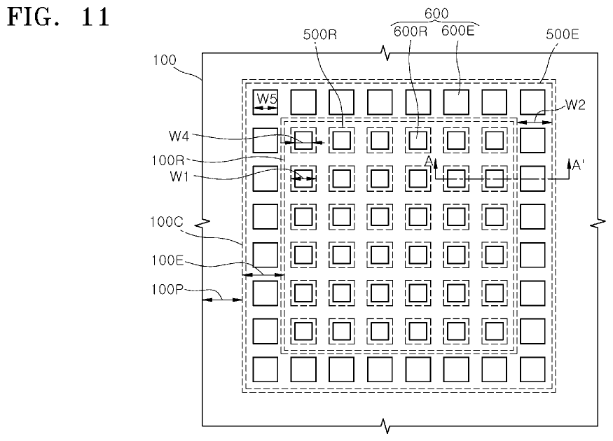

Referring to FIGS. 10 and 11, third conductive patterns 600 that are connected to the first conductive patterns 500R and the second conductive pattern 500E may be formed. A conductive layer that is connected or bonded to some parts of the first conductive patterns 500R and some parts of the second conductive pattern 500E, which are exposed to the openings 260H, may be formed by filling the openings 260H. The conductive layer may be separated into the third conductive patterns 600 by removing some parts of the conductive layer. The third conductive patterns 600 may each be separated in a form that fills each of the openings 260H. The third conductive pattern 600 may be formed to have a conductive pillar feature that fills each of the openings 260H. The third conductive pattern 600 may be formed to have a conductive cylindrical feature that extends along the profile of the openings 260H and that has a concave form. The third conductive pattern 600 may include a layer including metal, such as titanium nitride (TIN). The third conductive pattern 600 may further include a conductive polysilicon layer that is formed over titanium nitride (TIN). The third conductive patterns 600 may be formed in the form of island features or as an array of the island features.

The third conductive patterns 600 may include fourth conductive patterns 600R and fifth conductive patterns 600E. The fourth conductive patterns 600R, that is, some of the third conductive patterns 600, may be connected to the first conductive patterns 500R, respectively. The fifth conductive patterns 600E, that is, some others of the third conductive patterns 600, may be connected to the second conductive pattern 500E. A plurality of fifth conductive patterns 600E may be connected to one second conductive pattern 500E. The fifth conductive patterns 600E may be arranged to surround the fourth conductive patterns 600R or an array of the fourth conductive patterns 600R. The fifth conductive patterns 600E may be formed to be arranged in a direction in which the second conductive pattern 500E extends.

A width W5 of the fifth conductive pattern 600E may be formed to be greater than a width W4 of the fourth conductive pattern 600R. The width W5 of the fifth conductive pattern 600E may be smaller than the width W2 of the second conductive pattern 500E, which is taken along line A-A′. The width W4 of the fourth conductive pattern 600R may be smaller than the width W1 of the first conductive pattern 500R. Accordingly, the possibility that the fourth conductive patterns 600R may be overlapped and aligned with the first conductive patterns 500R can be improved because the width W1 of the first conductive patterns 500R is formed to be greater than the width W4 of the fourth conductive patterns 600R.

The possibility that the fifth conductive patterns 600E may be connected to the second conductive pattern 500E while overlapping the second conductive pattern 500E without deviating from the second conductive pattern 500E can be improved because the width W2 of the second conductive patterns 500E is formed to be greater than the width W5 of the fifth conductive patterns 600E. Furthermore, the possibility that the fifth conductive patterns 600E deviate from the second conductive pattern 500E and that the fifth conductive patterns 600E are not connected to the second conductive pattern 500E can be reduced. The possibility that the fifth conductive patterns 600E deviate from their locations at which the fifth conductive patterns 600E are formed can be reduced because the second conductive pattern 500E is formed to have the line form feature or the ring form feature. Accordingly, the fifth conductive patterns 600E can be connected to the second conductive pattern 500E more stably because the second conductive pattern 500E is formed to have a relatively greater width W2 and to also have the line form feature or the ring form feature as described above.

The third conductive patterns 600 may be formed to have a height H that is relatively greater than the width W4 or W5. The third conductive patterns 600 may be formed to have the height H that is relatively greater than the width W4 or W5 because the first sacrificial layer 260 and/or the second sacrificial layer 280 is formed to have a thickness that is relatively greater than the thickness of each of the first and second conductive patterns 500R and 500E.

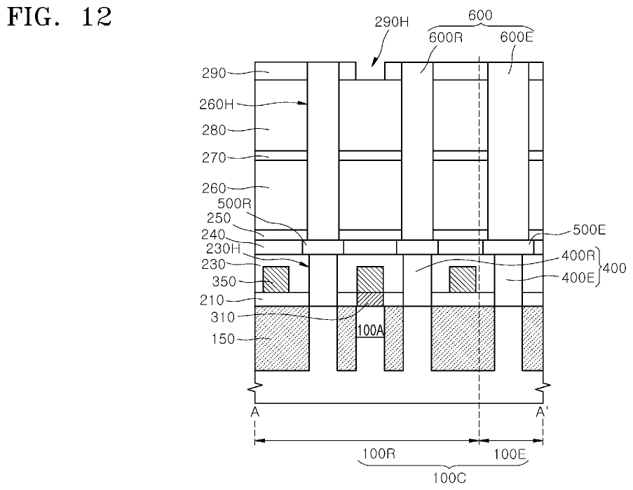

Referring to FIG. 12, an opening 290H or openings 290H that expose some part or some parts of the underlying second sacrificial layer 280 may be formed by selectively removing some part or some parts of the second floating support layer 290.

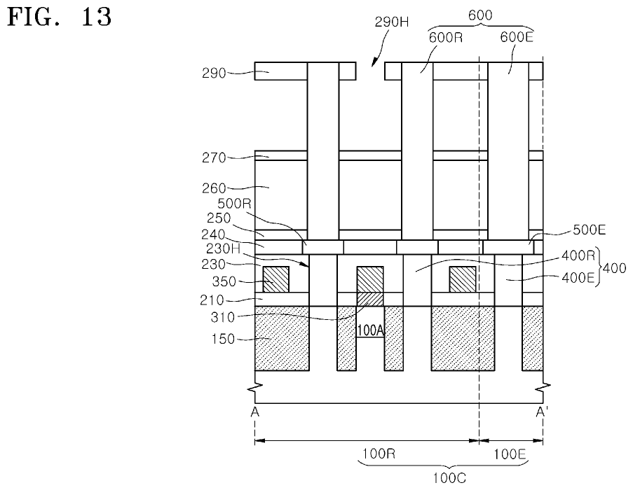

Referring to FIGS. 12 and 13, the second sacrificial layer 280 may be selectively removed through the opening 290H of the second floating support layer 290. As the second sacrificial layer 280 is removed, some parts of the side of the third conductive pattern 600 may be exposed. The second sacrificial layer 280 may be removed by an etchant or a chemical for etching by providing the etchant or the chemical to the second sacrificial layer 280 through the opening 290H of the second floating support layer 290.

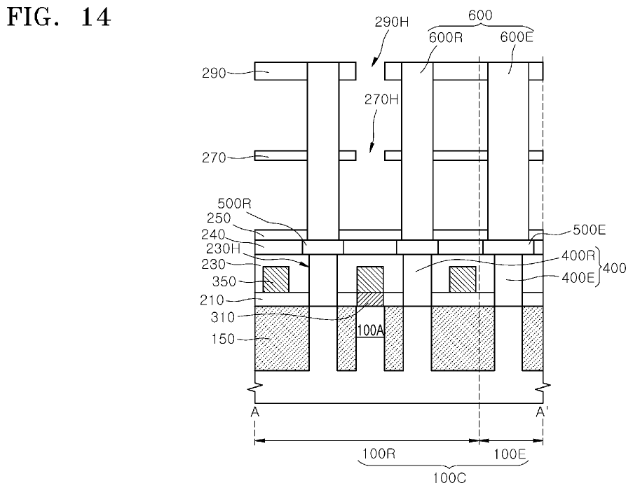

Referring to FIGS. 13 and 14, an opening 270H or openings 270H that expose some part or some parts of the underlying first sacrificial layer 260 may be formed by selectively removing some part or some parts of the first floating support layer 270, which are exposed as the second sacrificial layer 280 is removed, through the opening 290H or openings 290H of the second floating support layer 290. The first sacrificial layer 260 may be selectively removed through the opening 270H of the first floating support layer 270. As the first sacrificial layer 260 is removed, other some parts of the side of the third conductive pattern 600 may be exposed. The first sacrificial layer 260 may be removed by an etchant or a chemical for etching by providing the etchant or the chemical to the first sacrificial layer 260 through the opening 270H of the first floating support layer 270.

The remaining part of the first floating support layer 270 and the remaining part of the second floating support layer 290 may each play a role as a support that supports the third conductive patterns 600 by holding the third conductive patterns 600 so that the third conductive patterns 600 do not collapse. The remaining part of the first floating support layer 270 and the remaining part of the second floating support layer 290 may each be denoted as a nitride floating capacitor (NFC) structure.

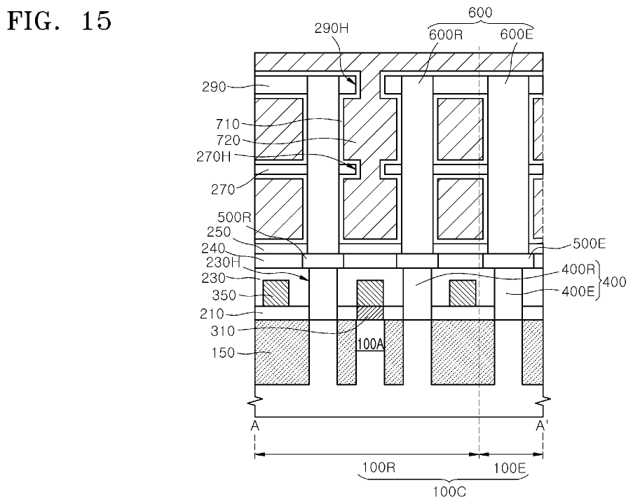

Referring to FIG. 15, a capacitor electric layer 710 that covers the third conductive patterns 600 may be formed. The capacitor electric layer 710 may extend to cover a surface of the third conductive patterns 600, which has been exposed as the first and second sacrificial layers (260 and 280 in FIG. 12) are removed, and to cover the first and second floating support layers 270 and 290. The capacitor electric layer 710 may include a dielectric material that constitutes a capacitor. The capacitor electric layer 710 may include a high dielectric material layer having a high dielectric constant (k). The capacitor electric layer 710 may include zirconium oxide (ZrO₂), aluminum oxide (Al₂O₃), or tantalum oxide (Ta₂O₅).

A plate node layer 720 that covers the capacitor electric layer 710 may be formed. The plate node layer 720 may include various electrode materials. The plate node layer 720 may include a titanium nitride (TiN) layer. The plate node layer 720 may further include a conductive silicon layer, such as, for example, a silicon germanium (SiGe) layer that covers the titanium nitride layer.

A capacitor structure including the third conductive patterns 600, the capacitor electric layer 710, and the plate node layer 720 may be constructed. The third conductive patterns 600 may act as storage nodes of the capacitor structure. The conductive contacts 400 that are electrically connected to the third conductive patterns 600 may each act as a storage node contact (SNC) that connects the capacitor structure to each of the active regions 100A of the semiconductor substrate 100. The first conductive patterns 500R and the second conductive pattern 500E may each act as a connection pad or a connection member that connects the capacitor structure or the storage nodes to the storage node contacts.

The first conductive contacts 400R, the first conductive patterns 500R, and the fourth conductive patterns 600R, which are disposed in the first region 100R of the semiconductor substrate 100 or disposed to overlap the first region 100R, may be elements that substantially construct the capacitor structure. In contrast, the second conductive contacts 400E, the second conductive pattern 500E, and the fifth conductive patterns 600E, which are disposed in the second region 100E of the semiconductor substrate 100 or disposed to overlap the second region 100E, may be dummy features that do not substantially operate as integrated circuits. The dummy features may be features that have been added so that the first conductive contacts 400R, the first conductive patterns 500R, and the fourth conductive patterns 600R have stabilized features. The dummy features may be features that have been added so that the first conductive contacts 400R, the first conductive patterns 500R, and the fourth conductive patterns 600R are formed conformally with features that are intended in the design.

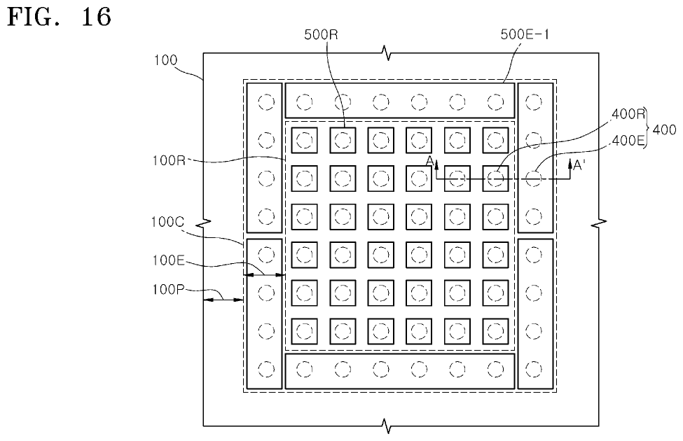

FIG. 16 is a simplified schematic plan view illustrating an array of the conductive patterns 500R and 500E-1 of a semiconductor device according to an embodiment. In FIG. 16, members that are presented to have the same reference numerals as those in FIG. 7 may indicate the same members as those of FIG. 7.

Referring to FIG. 16, a plurality of second conductive patterns 500E-1 may be arranged to surround the array of the first conductive patterns 500R or the first conductive patterns 500R. The plurality of second conductive patterns 500E-1 may be arranged along the second region 100E of the semiconductor substrate 100. The second conductive pattern 500E-1 may be formed to have a line form feature or bar shape that extends along the second region 100E of the semiconductor substrate 100.

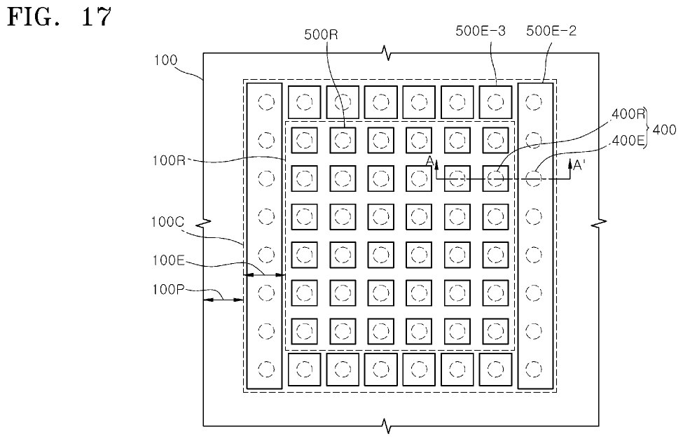

FIG. 17 is a simplified schematic plan view illustrating an array of conductive patterns 500R, 500E-2, and 500E-3 of a semiconductor device according to an embodiment. In FIG. 17, members that are presented to have the same reference numerals as those in FIG. 7 may indicate the same members as those of FIG. 7.

Referring to FIG. 17, a plurality of second conductive patterns 500E-2 may be disposed outside the array of the first conductive patterns 500R or the first conductive patterns 500R. The plurality of second conductive patterns 500E-2 may be formed to have a line form feature or bar shape that extends lengthwise along the second region 100E of the semiconductor substrate 100. The second conductive patterns 500E-2 may be disposed to face each other with the first conductive patterns 500R interposed between the second conductive patterns 500E-2 so that the second conductive patterns 500E-2 are spaced apart from each other. Sixth conductive patterns 500E-3 may be further disposed in the second region 100A of the semiconductor substrate 100 in the form of island features.

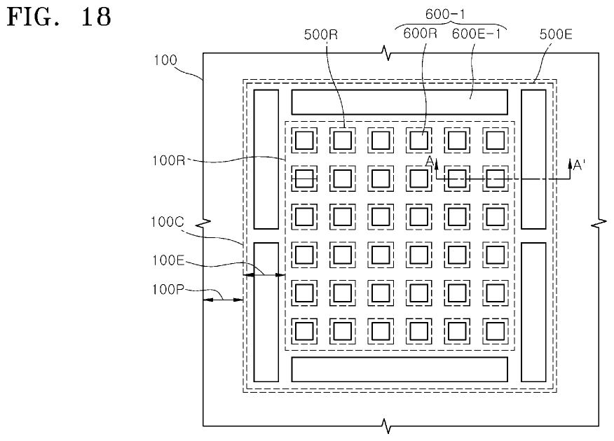

FIG. 18 is a simplified schematic plan view illustrating an array of conductive patterns 500R, 500E, and 600E-1 of a semiconductor device according to an embodiment. In FIG. 18, members that are presented to have the same reference numerals as those in FIG. 11 may indicate the same members as those of FIG. 11.

Referring to FIG. 18, third conductive patterns 600-1 may include fourth conductive patterns 600R and fifth conductive patterns 600E-1. A plurality of fifth conductive patterns 600E-1 may be formed to surround the array of the fourth conductive patterns 600R or the fourth conductive patterns 600R. The plurality of fifth conductive patterns 600E-1 may be arranged along the second region 100E of the semiconductor substrate 100. The fifth conductive pattern 600E-1 may be formed to have a line form feature or bar shape that extends along the second region 100E of the semiconductor substrate 100. The fifth conductive patterns 600E-1 can be bonded or connected to the second conductive pattern 500E in a wider area because the fifth conductive patterns 600E-1 each have the line form feature or the bar shape.

Referring back to FIGS. 11 and 18, in the process of simultaneously forming the fourth conductive patterns 600R and the fifth conductive pattern 600E and 600E-1, the possibility that the fourth and fifth conductive patterns 600E and 600E-1 will be lost can be reduced because the second conductive pattern 500E has the line form feature or the ring form feature. As presented with reference to FIGS. 13 and 14, in the process of removing the sacrificial layers 260 and 280, the fifth conductive patterns 600E and 600E-1 may be undesirably lost because the fifth conductive patterns 600E and 600E-1 may be swept by an etchant, a chemical, or a cleaner. There is a good possibility that the fifth conductive patterns 600E and 600E-1 will be more lost than the fourth conductive patterns 600R because the fifth conductive patterns 600E and 600E-1 are disposed in the outskirts of edges of the outside of the fourth conductive patterns 600R.

If a second conductive pattern has an island feature like the first conductive pattern 500R, the fifth conductive patterns 600E and 600E-1 may be misaligned with the second conductive pattern, so that the fifth conductive patterns 600E and 600E-1 may not be connected to the second conductive pattern. As the fifth conductive patterns 600E and 600E-1 are misaligned with the second conductive pattern, bonding strength may be relatively small because the fifth conductive patterns 600E and 600E-1 are partially connected to the second conductive pattern. Accordingly, the possibility that the fifth conductive patterns 600E and 600E-1 will be more lost than the fourth conductive patterns 600R during the capacitor processing process may be increased.

Although the fifth conductive patterns 600E and 600E-1 are misaligned with the second conductive pattern 500E, there is a relatively good possibility that the fifth conductive patterns 600E and 600E-1 will be connected or bonded to the second conductive pattern 500E because the second conductive pattern 500E has the line form feature or the ring form feature. The possibility that the fifth conductive patterns 600E and 600E-1 will be lost during the capacitor manufacturing process can be reduced because the fifth conductive patterns 600E and 600E-1 can be connected to the second conductive pattern 500E relatively strongly or through a wide interface.

The embodiments of the present disclosure have been described so far. A person having ordinary knowledge in the art to which the present invention pertains will understand that the present invention may be implemented in a modified form without departing from an intrinsic characteristic of the present disclosure. Accordingly, the disclosed embodiments should be considered from a descriptive viewpoint, and should not limit the scope of the present invention.

What is claimed is:

1. A semiconductor device comprising:
first conductive patterns disposed over an insulating layer formed over a semiconductor substrate;
a second conductive pattern disposed to extend lengthwise to a side of the first conductive patterns over the insulating layer; and
third conductive patterns connected to the first conductive patterns and the second conductive pattern.

2. The semiconductor device of claim 1, wherein:
the first conductive patterns are formed to have island features that are spaced apart from each other and disposed at predetermined intervals, and
the second conductive pattern is formed to have a line form feature that laterally faces the island features.

3. The semiconductor device of claim 1, wherein the second conductive pattern is formed to have a greater width than each of the first conductive patterns.

4. The semiconductor device of claim 1, wherein the second conductive pattern is formed to extend to surround an outside of the first conductive patterns.

5. The semiconductor device of claim 1, wherein the second conductive pattern is formed to surround an outside of the first conductive patterns in a ring form feature.

6. The semiconductor device of claim 1, wherein:
the semiconductor substrate comprises a first region and a second region that surrounds the first region,
the first conductive patterns are disposed within the first region of the semiconductor substrate, and
the second conductive pattern is disposed within the second region of the semiconductor substrate.

7. The semiconductor device of claim 1, further comprising conductive contacts that penetrate the insulating layer and that electrically connect the first conductive patterns and the second conductive pattern to the semiconductor substrate.

8. The semiconductor device of claim 7, wherein
the conductive contacts include first conductive contacts and second conductive contacts,
the first conductive patterns are connected to the first conductive contacts, respectively, and
the second conductive patterns are connected to the second conductive contacts, respectively.

9. The semiconductor device of claim 1, wherein:
the third conductive patterns include fourth conductive patterns and fifth conductive patterns,
the fourth conductive patterns are connected to the first conductive patterns, respectively, and
a plurality of the fifth conductive patterns is connected to the second conductive pattern.

10. The semiconductor device of claim 9, wherein the fifth conductive patterns are formed to have a bar shape that extends lengthwise along the second conductive pattern.

11. The semiconductor device of claim 9, wherein each of the fifth conductive patterns is formed to have a greater width than each of the fourth conductive patterns.

12. The semiconductor device of claim 1, wherein the third conductive patterns are formed as storage nodes of capacitors.

13. The semiconductor device of claim 1, further comprising a floating support layer that is spaced apart from the insulating layer and that supports the third conductive patterns.
